(19) United States
(12) Patent Application Publication
(10) Pub. No.: US 2006/0263729 A1
(43) Pub. Date: Nov. 23, 2006

(54) Surface treatment of a dry-developed hard mask and surface treatment compositions used therefor

(75) Inventors: Kevin Shea, Boise, ID (US); Kevin Torek, Meridian, ID (US)

Correspondence Address: SCHWEGMAN, LUNDBERG, WOESSNER & KLUTH, P.A., P.O. BOX 2938, MINNEAPOLIS, MN, 55402, US

(73) Assignee: Micron Technology, Inc.

(21) Appl. No.: 11/494,056

(22) Filed: Jul. 27, 2006

Related U.S. Application Data
(62) Division of application No. 10/788,889, filed on Feb. 27, 2004.

(51) Int. Cl. G03F 7/26

(52) U.S. Cl. 430/311; 430/329; 430/950

(57) ABSTRACT

A surface treatment process includes rinsing a substrate after a dry development process to remove residual resist material prior to patterning a hard mask layer. An amorphous carbon hard mask is dry developed and thereafter, the surface treatment includes an aqueous ammonium hydroxide and hydrogen peroxide composition. While the composition acts as a solvent to the resist, the composition is selective to the amorphous carbon hard mask and the surface under the hard mask.

### RELATED APPLICATIONS

This application is a Divisional of U.S. application Ser. No. 10/788,889, filed Feb. 27, 2004, which is incorporated herein by reference.

### TECHNICAL FIELD

An embodiment of this disclosure relates to semiconductor fabrication methods. More particularly, an embodiment relates to a surface treatment process that follows a dry development of a hard mask.

### BACKGROUND INFORMATION

The importance of minimizing contamination during semiconductor fabrication processes has been recognized since the early days of the industry. Miniaturization is the process of crowding more semiconductive devices onto a smaller substrate area in order to achieve better device speed, lower energy usage, and better device portability, among others. New processing methods must often be developed to enable miniaturization to be realized. As semiconductor devices have become smaller and more complex, cleanliness requirements have become increasingly stringent, especially for devices with submicron critical dimensions, because the ability to reliably create multi-level metallization structures is increasingly vital. The importance of cleaning and conditioning submicron devices during the fabrication process is also emphasized because small-scale residues that may not have seriously affected the performance these devices.

Dry development processes are used in preparing patterned hard masks. The removal of photoresist material (hereinafter “resist”) is challenging since the hard mask material is often amorphous carbon, and the resist is often a carbon-rich composition. During the dry development process, some dry-developed resist can become pooled-up on surfaces that need to be clear for subsequent processing. The pooled-up resist presents a challenge for the fabricator because is represents an unacceptably dirty wafer for further processing. A further challenge is to remove resist from the edges of a wafer, as the resist is often thicker (known as an “edge bead”) near the edges due to its mode of being applied to the wafer. Consequently, as residues from the resist tend to pooled-up in some areas and as edge-bead resist tends to be present at the edge of the wafer. Unremoved resist can be mobilized during subsequent processing that creates further undesirable results during the etch process that uses the hard mask.

As the removal of dry-developed residues grows increasingly important in the miniaturization trend, there is a need for an effective method of removal of these residues that can be easily implemented in standard wafer processing equipment and has reduced costs for chemical purchase and disposal.

### BRIEF DESCRIPTION OF THE DRAWINGS

In order to illustrate the manner in which embodiments are obtained, a more particular description will be rendered by reference to specific embodiments that are illustrated in the appended drawings. Understanding that these drawings depict only typical embodiments that are not necessarily drawn to scale and are not therefore to be considered to be limiting of its scope, the embodiments will be described and explained with additional specificity and detail through the use of the accompanying figures in which:

FIG. 1A is a cross section of a semiconductive structure including a resist stack according to an embodiment;

FIG. 1B is a cross section of the structure depicted in FIG. 1A after patterning some of the resist stack according to an embodiment;

FIG. 1C is a cross section of the structure depicted in FIG. 1B after patterning of a hard mask layer according to an embodiment;

FIG. 1D is a cross section of the structure depicted in FIG. 1C after surface treating according to an embodiment; and

FIG. 2 is a process flow diagram according to an embodiment.

### DETAILED DESCRIPTION

In the following detailed description, reference is made to the accompanying drawings that form a part hereof, and in which is shown, by way of illustration, specific ways that embodiments may be practiced. In the drawings, like numerals describe substantially similar components throughout the several views. These embodiments are described in sufficient detail to enable those skilled in the art to practice various embodiments. Other embodiments may be utilized and structural, logical, and electrical changes may be made without departing from the scope of the various embodiments. The terms wafer and substrate used in the following description include any structure having an exposed surface with which to form an integrated circuit (“IC”) structure embodiment.

The term substrate is understood to include semiconductor wafers. The term substrate is also used to refer to semiconductor structures during processing, and may include other layers that have been fabricated thereupon. Both wafer and substrate include doped and undoped semiconductors, epitaxial semiconductor layers supported by a base semiconductor or insulator, as well as other semiconductor structures well known to one skilled in the art. The term conductor is understood to include semiconductors, and the term insulator or dielectric is defined to include any material that is less electrically conductive than the materials referred to as conductors.

The term “horizontal” as used in this application is defined as a plane parallel to the conventional plane or surface of a wafer or substrate, regardless of the orientation of the wafer or substrate. The term “vertical” refers to a direction perpendicular to the horizontal as defined above. Prepositions, such as “on”, “side” (as in “sidewall”), “higher”, “above”, “lower”, “over”, “below”, and “under” are defined with respect to the conventional plane or surface being on the top surface of the wafer or substrate, regardless of the orientation of the wafer or substrate.

Unless otherwise specified, the process term “selective” is intended to mean, for example, an etch that is selective to a given substance, is selective to leaving that substance substantially intact in relation to a substance that is to be removed by the etch.

The following detailed description is, therefore, not to be taken in a limiting sense, and the scope of the present invention is defined only by the appended claims, along with the full scope of equivalents to which such claims are entitled.

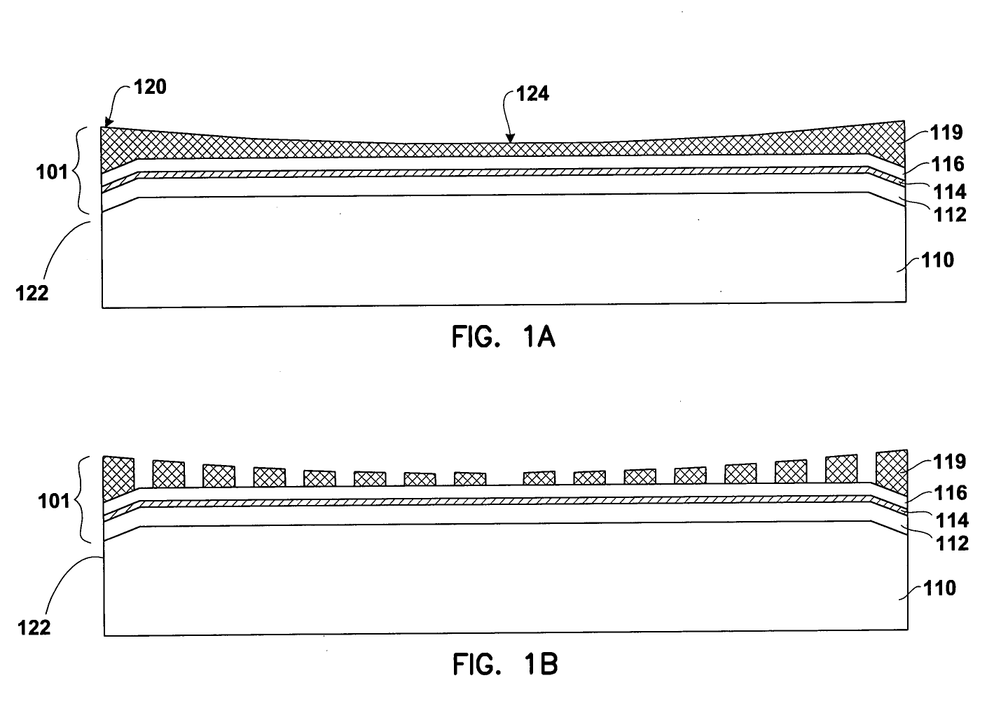

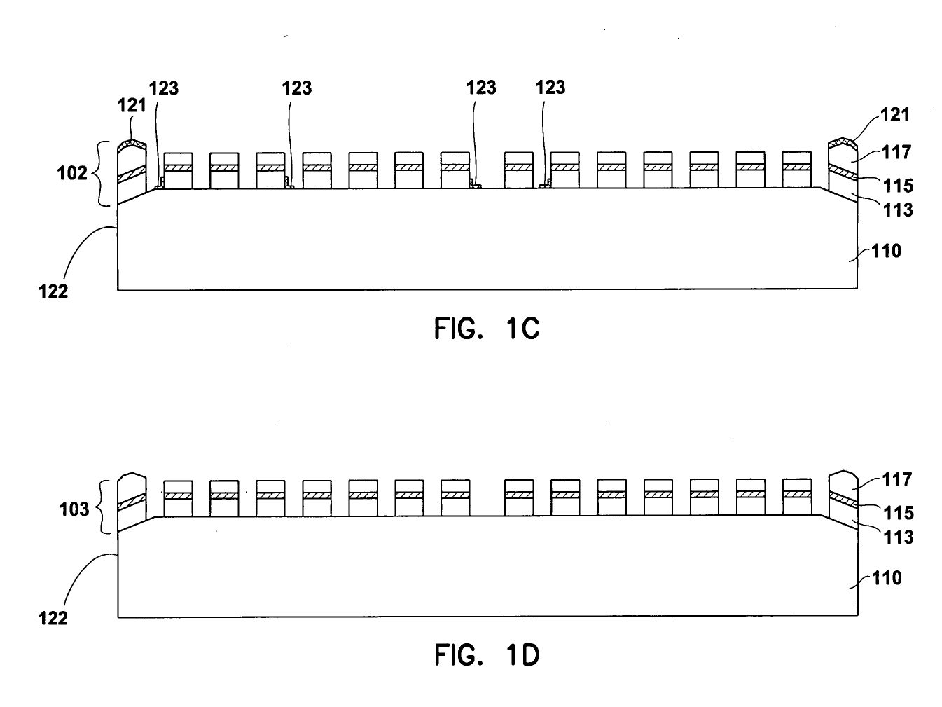

FIG. 1A is a cross section of a semiconductive structure including a resist stack 100 according to an embodiment. A resist stack 100 is configured upon a wafer that includes a semiconductive substrate 110 and a carbon-containing hard mask layer 112 that is disposed above and on the semiconductive substrate 110. In an embodiment, the semiconductive substrate 110 includes an active area (not pictured) and an active device such as a transistor, an inductor, a capacitor, a resistor, and other devices. In an embodiment, a dielectric antireflective coating 114 (“DARC”) is disposed above the carbon-containing hard mask layer 112. In an embodiment, a bottom antireflective coating 116 (“BARC”) is disposed above the DARC 116.

FIG. 1A also illustrates a resist layer 118 that has been spun on and cured over the semiconductive substrate 110. The resist layer 118 is depicted as having a variable thickness that has a thicker region 120 (also referred to as an edge bead 120) at the wafer edge 122 and a thinner region 124 at or near the geometric middle of the wafer surface that holds the resist stack 100.

FIG. 1B is a cross section of the structure depicted in FIG. 1A after patterning some of the resist layer 118 (FIG. 1A) according to an embodiment. The resist stack 101 is depicted with the resist layer 118 (FIG. 1A) being patterned into a patterned resist layer 119. The patterned resist layer 119 is depicted with an arbitrary pattern across the surface of the BARC 116 if it is present. In an embodiment, only the DARC 114 is present as an antireflective coating.

FIG. 1C is a cross section of the structure depicted in FIG. 1B after patterning of the hard mask layer according to an embodiment. The resist stack 102 is depicted after a dry develop process that removes exposed portions of the DARC 114 (FIG. 1B) to achieve a patterned DARC 115. Optionally if a BARC 116 (FIG. 1B) is present, the wafer is depicted after the dry develop process that removes exposed portions of the BARC 116 to achieve a patterned BARC 117. And additionally, the resist stack 102 is depicted after the after a dry develop process (“ADD”) that removes exposed portions of the hard mask layer 112 to achieve a patterned hard mask 113.

FIG. 1C also depicts residual resist 121 in semi-arbitrary quantities along the wafer. Additionally, mobilized residual resist 123 is depicted as having pooled up and collected in locations that will hinder a dry etch through the patterned hard mask 113 into the semiconductive substrate 110.

Various process embodiments are useful in surface treating the semiconductive substrate 110. The various surface treating embodiments are related to preserving the patterned hard mask 113, while removing the carbon-containing resist materials. Several processing embodiments and surface treating composition embodiments are set forth in this disclosure. The several surface treating processes can be understood by reference to FIGS. 1C and 1D.

FIG. 1D is a cross section of the structure depicted in FIG. 1C after surface treating according to an embodiment. The resist stack 103 is depicted after surface treating that includes a process. In an embodiment, the process begins with patterning the carbon-containing hard mask 113 over a substrate 110 with the patterned resist 119 as depicted in FIG. 1C. Thereafter, the process concludes with surface treating the substrate 110 to remove residual resist 121 and 123 (FIG. 1C) under conditions that are selective to the patterned hard mask 113 and to the semiconductive substrate 110 as depicted in FIG. 1D.

Various process embodiments are useful in surface treating the semiconductive substrate 110. The various surface treating embodiments are related to preserving the patterned hard mask 113, while removing the carbon-containing resist materials.

In an embodiment, the carbon-containing hard mask 113 includes amorphous carbon. Surface treating includes using an aqueous ammonium hydroxide and hydrogen peroxide solution. In an embodiment, the aqueous ammonium hydroxide and hydrogen peroxide solution is in a concentration ratio of H₂O:NH₄OH:H₂O₂ that is from about 100:3:2 to about 5:1:2.

In an embodiment, the carbon-containing hard mask 113 includes amorphous carbon, and surface treating includes using an aqueous ammonium hydroxide and hydrogen peroxide solution in an H₂O:NH₄OH:H₂O₂ concentration ratio from about 5:1:1 to about 5:1:2. In an embodiment, the carbon-containing hard mask 113 includes amorphous carbon, and surface treating includes using an aqueous ammonium hydroxide and hydrogen peroxide solution in an H₂O:NH₄OH:H₂O₂ concentration ratio from about 100:1:2 to about 100:3:2. In an embodiment, the carbon-containing hard mask 113 includes amorphous carbon, and surface treating includes using an aqueous ammonium hydroxide and hydrogen peroxide solution in an H₂O:NH₄OH:H₂O₂ concentration ratio from about 100:1:1 to about 100:3:3. In an embodiment, surface treating includes an aqueous ammonium hydroxide and hydrogen peroxide solution that is applied in a time range from about 2 minutes to about 45 minutes. In an embodiment, the carbon-containing hard mask 113 includes amorphous carbon, and surface treating includes an aqueous ammonium hydroxide and hydrogen peroxide solution that is applied in a temperature range from about room temperature to about 70° C.

In an example, an amorphous carbon hard mask was dry developed over a semiconductive substrate of borophosphosilicate glass (“BPSG”). The dry-develop process left residual resist. A surface treating process was undertaken with an aqueous ammonium hydroxide and hydrogen peroxide solution in an H₂O:NH₄OH:H₂O₂ concentration ratio of about 100:3:2, at about 55° C. and for about 10 minutes. No residual resist was detected by conventional microscopic analysis techniques. Further, no detectible attack on the amorphous carbon or of the substrate was detected by the same technique.

Although the semiconductive substrate 110 is depicted as BPSG in the above example, other substrates are also used in this disclosure. In an embodiment, a phosophosilicate glass (“PSG”) substrate is used. In an embodiment, a borophosilicate glass (“BSG”) substrate is used. In an embodiment, a silica substrate is used. In an embodiment, an alumina substrate is used. In an embodiment, a thoria substrate is used. In an embodiment, a ceria substrate is used. In an embodiment, a nitride substrate is used. In an embodiment, the nitride substrate is silicon nitride, SiₓN_{y}. In this nitride substrate, x is equal to about 3 and y is equal to about 4.

In another example, an amorphous carbon hard mask was dry developed over a semiconductive substrate that included BPSG. The dry-develop process left residual resist. A surface treating process was undertaken with an aqueous ammonium hydroxide and hydrogen peroxide solution in an H₂O:NH₄OH:H₂O₂ concentration ratio of about 100:3:2, at about 55° C. and for about 20 minutes. No residual resist was detected. Further, no detectible attack on the amorphous carbon or of the substrate was detected.

In yet another example, an amorphous carbon hard mask was dry developed over a semiconductive substrate that included BPSG. The dry-develop process left residual resist. A surface treating process was undertaken with an aqueous ammonium hydroxide and hydrogen peroxide solution in an H₂O:NH₄OH:H₂O₂ concentration ratio of about 100:3:2, at about 55° C. and for about 5 minutes. Some residual resist was detected, but the amount of residual resist was less than the amount left ADD. Significantly, no detectible attack on the amorphous carbon or of the substrate was detected.

In yet another example, an amorphous carbon hard mask was dry developed over a semiconductive substrate that included BPSG. The dry-develop process left residual resist. A surface treating process was undertaken with an aqueous ammonium hydroxide and hydrogen peroxide solution in an H₂O:NH₄OH:H₂O₂ concentration ratio of about 100:3:2, at about 35° C. and for about 30 minutes. Some residual resist was detected, but the amount of residual resist was less than the amount left ADD. Significantly, no detectible attack on the amorphous carbon or of the substrate was detected.

In yet another example, an amorphous carbon hard mask was dry developed over a semiconductive substrate that included BPSG. Some residual resist was detected ADD. A surface treating process was undertaken with an aqueous ammonium hydroxide and hydrogen peroxide solution in an H₂O:NH₄OH:H₂O₂ concentration ratio of about 5:1:1, at about 55° C. and for about 10 minutes. No residual resist was detected, and no detectible attack on the amorphous carbon or of the substrate was detected.

In yet another example, an amorphous carbon hard mask was dry developed over a semiconductive substrate that included BPSG. Some residual resist was detected ADD. A surface treating process was undertaken with an aqueous ammonium hydroxide and hydrogen peroxide solution in an H₂O:NH₄OH:H₂O₂ concentration ratio of about 5:1:1, at about 70° C. and for about 10 minutes. No residual resist was detected, and no detectible attack on the amorphous carbon or of the substrate was detected.

In an embodiment, a second surface treating composition is added to the aqueous ammonium hydroxide and hydrogen peroxide solution. In an embodiment, the second surface treating composition includes aqueous sulfuric acid and citric acid solution. In an embodiment, the second surface treating composition includes aqueous sulfuric acid and hydrogen peroxide solution. In an embodiment, the second surface treating composition includes Aleg® 820 solution, manufactured by Mallinckrodt Baker, Inc. of St. Louis, Mo. In an embodiment, the second surface treating composition includes ozone with dilute ammonium hydroxide in a ratio of about 1000:1:100 H₂O:O₃:NH₄OH to about 1000:2:100.

In an embodiment, the second surface treating composition includes, and ozone with dilute hydrogen fluoride; often referred to as “fluorozone”. In an embodiment, the second surface treating composition includes ozone with dilute hydrogen fluoride in a ratio of about 1000:1:100 H₂O:O₃:HF to about 1000:2:100.

In an example, an aqueous ammonium hydroxide and hydrogen peroxide solution is provided in a majority proportion in a solution mixture, and a minority proportion of at least one of the above-mentioned compositions is provided as the balance of the solution mixture. By “majority proportion”, it is understood that at least 50 percent of the solution mixture includes an aqueous ammonium hydroxide and hydrogen peroxide solution, such as the 100:3:2 solution, the 5:1:1 solution, or any of the other given aqueous ammonium hydroxide and hydrogen peroxide solutions. An amorphous carbon hard mask is dry developed over a semiconductive substrate. A surface treating process is undertaken with the given solution mixture.

In another example, an aqueous ammonium hydroxide and hydrogen peroxide solution is provided in a plurality proportion in a solution mixture, and a minority proportion of at least two of the above-mentioned compositions is provided as the balance of the solution mixture. By “plurality proportion”, it is understood that the solution mixture includes the largest presence by volume of an aqueous ammonium hydroxide and hydrogen peroxide solution, such as the 100:3:2 solution, the 5:1:1 solution, or any of the other given aqueous ammonium hydroxide and hydrogen peroxide solutions. It is further understood that the at least two of the above-mentioned compositions includes equal volumes of the at least two compositions, or at least one volume is greater than the other. In any event, the total volume equals 100 percent of the solution mixture. An amorphous carbon hard mask is dry developed over a semiconductive substrate. A surface treating process is undertaken with the given solution mixture.

In another example a 45 percent aqueous ammonium hydroxide and hydrogen peroxide solution is combined with a 40 percent first above-mentioned composition, and with a 15 percent second above-mentioned composition to make the total solution mixture. An amorphous carbon hard mask is dry developed over a semiconductive substrate. A surface treating process is undertaken with the given solution mixture.

In another example a 45 percent aqueous ammonium hydroxide and hydrogen peroxide solution is combined with a 30 percent first above-mentioned composition, and with a 25 percent second above-mentioned composition to make the total solution mixture. An amorphous carbon hard mask is dry developed over a semiconductive substrate. A surface treating process is undertaken with the given solution mixture.

In another example a 40 percent aqueous ammonium hydroxide and hydrogen peroxide solution is combined with a 35 percent first above-mentioned composition, and with a 25 percent second above-mentioned composition to make the total solution mixture. An amorphous carbon hard mask is dry developed over a semiconductive substrate. A surface treating process is undertaken with the given solution mixture.

In an example, a majority proportion of aqueous ammonium hydroxide and hydrogen peroxide solution is provided in an H₂O:NH₄OH:H₂O₂ concentration ratio of about 100:3:2. A minority proportion of aqueous ammonium hydroxide and hydrogen peroxide solution is provided in an H₂O:NH₄OH:H₂O₂ concentration ratio of about 5:1:1. An amorphous carbon hard mask is dry developed over a semiconductive substrate. A surface treating process is undertaken with the given solution mixture.

In another example, a plurality proportion of aqueous ammonium hydroxide and hydrogen peroxide solution is provided in an H₂O:NH₄OH:H₂O₂ concentration ratio of about 100:3:2. A first minority proportion of aqueous ammonium hydroxide and hydrogen peroxide solution is provided in an H₂O:NH₄OH:H₂O₂ concentration ratio of about 5:1:1. A second minority proportion of at least one solution selected from aqueous sulfuric acid and citric acid solution, aqueous sulfuric and hydrogen peroxide solution, Aleg® 820 solution, ozone with dilute ammonium hydroxide, and ozone with dilute hydrogen fluoride. An amorphous carbon hard mask is dry developed over a semiconductive substrate. A surface treating process is undertaken with the given solution mixture.

In an embodiment, an aqueous sulfuric acid and carboxylic acid solution is used ADD to surface treat a substrate to remove residual resist. In an embodiment, the carboxylic acid includes citric acid. The surface treating process includes using an aqueous sulfuric acid and citric acid solution in an H₂O:H₂SO₄:C₆H₄O₇ concentration ratio of about 100:3:2 to about 100:2:2.

In an example, an amorphous carbon hard mask was dry developed over a semiconductive substrate that included BPSG. Some residual resist was detected ADD. A surface treating process was undertaken with an aqueous sulfuric acid and citric acid solution in an H₂O:H₂SO₄:C₆H₄O₇ concentration ratio of about 100:3:2, at about 50° C. and for about 10 minutes. No residual resist was detected, and no detectible attack on the amorphous carbon or of the substrate was detected.

In an example, an aqueous sulfuric acid and citric acid solution is provided in a majority proportion in a solution mixture, and a minority proportion of at least one of the above-mentioned compositions, including aqueous ammonium hydroxide and hydrogen peroxide solution, as the balance of the solution mixture. An amorphous carbon hard mask is dry developed over a semiconductive substrate. A surface treating process is undertaken with the given solution mixture.

In another example, an aqueous sulfuric acid and citric acid solution is provided in a plurality proportion in a solution mixture, and a minority proportion of at least two of the above-mentioned compositions is provided as the balance of the solution mixture. An amorphous carbon hard mask is dry developed over a semiconductive substrate. A surface treating process is undertaken with the given solution mixture.

In another example a 45 percent aqueous sulfuric acid and citric acid solution is combined with a 40 percent first above-mentioned composition, and with a 15 percent second above-mentioned composition to make the total solution mixture. An amorphous carbon hard mask is dry developed over a semiconductive substrate. A surface treating process is undertaken with the given solution mixture.

In another example a 45 percent aqueous sulfuric acid and citric acid solution is combined with a 30 percent first above-mentioned composition, and with a 25 percent second above-mentioned composition to make the total solution mixture. An amorphous carbon hard mask is dry developed over a semiconductive substrate. A surface treating process is undertaken with the given solution mixture.

In another example a 40 percent aqueous sulfuric acid and citric acid solution is combined with a 35 percent first above-mentioned composition, and with a 25 percent second above-mentioned composition to make the total solution mixture. An amorphous carbon hard mask is dry developed over a semiconductive substrate. A surface treating process is undertaken with the given solution mixture.

In an embodiment where a solution mixture is used with either a majority or a plurality mixture, a minority composition is included that has the ingredients of what is known as a “piranha etc”. In an embodiment, the piranha etch composition includes mixtures of 98 percent H₂SO₄ and 30 percent H₂O₂ in volume ratios of 4:1. Accordingly, an embodiment includes any of the above-referenced compositions in one of a majority or a plurality volume ratio, and a piranha etch composition is present as a minority volume ratio in the solution mixture.

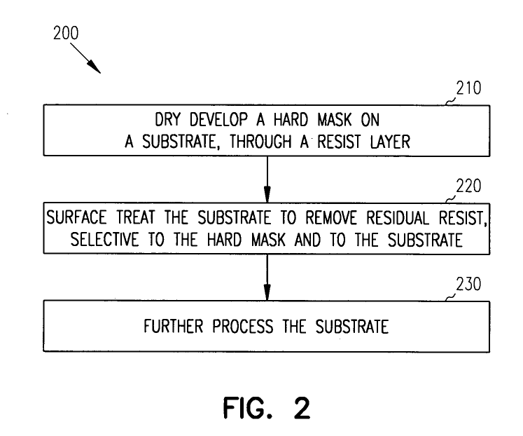

FIG. 2 is a process flow diagram according to an embodiment. The process 200 includes substrate preparation such as the formation of active devices in semiconductive material. At 210 a substrate with a hard mask layer is dry developed. By way of non-limiting example, the hard mask layer 112 is patterned to form the patterned hard mask 113 as depicted in FIGS. 1A through 1C. At 220, the substrate is surface treated to remove residual resist and other material. By way of non-limiting example, surface treating uses any of the disclosed surface treating processes as taught or claimed, including their equivalents. At 230, further processing is carried out. In an embodiment, the further processing includes a rinse before etching the substrate. By way of non-limiting example, a rinse process includes a deionized water rinse. In an embodiment a dry etch is the further processing. The dry etch uses the patterned hard mask. By way of non-limiting example, a trench etch is carried out that uses the patterned hard mask.

### CONCLUSION

Thus has been shown processes that result in a surface treated substrate that removes residual resist, but that is selective to leaving a carbon-containing hard mask as well as the substrate upon which the hard mask is patterned. Thereby, the subsequent processing such as a dry trench etch is carried out without the encumbrances of residual material adversely affecting the integrity of the etch process.

A process includes surface treating a substrate after dry developing a hard mask under a resist stack. In an embodiment, a process includes patterning a carbon-containing hard mask over a substrate with a resist stack. Thereafter, the process includes surface treating the substrate to remove residual resist under conditions that are selective to the hard mask and to the substrate.

In an embodiment, the surface treating process includes an amorphous carbon hard mask. The surface treating process includes using an aqueous ammonium hydroxide and hydrogen peroxide solution.

In an embodiment, a second surface treating composition is added to the aqueous ammonium hydroxide and hydrogen peroxide solution. In an embodiment, the second surface treating composition includes aqueous sulfuric acid and citric acid solution. In an embodiment, the second surface treating composition includes aqueous sulfuric acid and hydrogen peroxide solution. In an embodiment, the second surface treating composition includes Aleg® 820 solution, manufactured by Mallinckrodt Baker, Inc. of St. Louis, Mo. In an embodiment, the second surface treating composition includes ozone with dilute ammonium hydroxide. In an embodiment, the second surface treating composition includes, and ozone with dilute hydrogen fluoride; often referred to as “fluorozone”.

In an embodiment, the surface treating composition includes at least three of the above-referenced compositions in a solution mixture. In an embodiment, any of the above-referenced compositions is used alone in a surface treating process embodiment.

The Abstract is provided to comply with 37 C.F.R. §1.72(b) requiring an Abstract that will allow the reader to quickly ascertain the nature and gist of the technical disclosure. It is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment.

While various embodiments have been described and illustrated with respect to surface treating structures, it should be apparent that the same processing techniques can be used to surface treat other structures by the techniques set forth in this disclosure for other applications. Furthermore, the processes described herein may be used in the development of other semiconductor structures, such as gates, interconnects, contact pads, and more.

Although specific embodiments have been illustrated and described herein, it will be appreciated by those of ordinary skill in the art that any arrangement which is calculated to achieve the same purpose may be substituted for the specific embodiments shown. Many adaptations of the invention will be apparent to those of ordinary skill in the art. Accordingly, this application is intended to cover any adaptations or variations of the invention. It is manifestly intended that this invention be limited only by the following claims and equivalents thereof.

What is claimed is:

1. A process comprising:
patterning an amorphous carbon hard mask with a resist stack over a substrate, the resist stack including:
at least one antireflective coating disposed over the hard mask, selected from a dielectric antireflective coating and a bottom antireflective coating; and
a photo resist layer disposed over the at least one antireflective coating; and
surface treating the substrate to remove residual photo resist under conditions that are selective to leaving the hard mask, the at least one antireflective coating, and the substrate.

2. The process of claim 1, wherein surface treating includes rinsing the photo resist with a solution selected from aqueous ammonium hydroxide and hydrogen peroxide solution, aqueous sulfuric acid and citric acid solution, aqueous sulfuric acid and hydrogen peroxide solution, Aleg 820 solution, ozone with dilute ammonium hydroxide, ozone with dilute hydrogen fluoride, and combinations thereof.

3. The process of claim 1, wherein surface treating includes using a water, ammonium hydroxide and hydrogen peroxide solution in an H₂O:NH₄OH:H₂O₂ concentration ratio from about 5:1:1 to about 100:3:2, a time range from about 2 minutes to about 45 minutes, and a temperature range from about room temperature to about 70° C.

4. The process of claim 1, wherein surface treating includes using a water, ammonium hydroxide and hydrogen peroxide solution in an H₂O:NH₄OH:H₂O₂ concentration ratio of about 100:3:2, a time range from about 10 minutes to about 20 minutes, and a temperature range from about 30° C. to about 60° C.

5. A process comprising:
patterning an amorphous carbon hard mask with a resist stack over a substrate, the resist stack including:
at least one antireflective coating disposed over the hard mask, selected from a dielectric antireflective coating and a bottom antireflective coating; and
a photo resist layer disposed over the at least one antireflective coating; and
surface treating the substrate to remove residual photo resist under conditions that are selective to leaving the hard mask, the at least one antireflective coating, and the substrate, wherein surface treating includes using a water, ammonium hydroxide and hydrogen peroxide solution in an H₂O:NH₄OH:H₂O₂ concentration ratio of about 100:3:2, and a temperature of about 55° C.

6. The process of claim 5, wherein surface treating includes a surface treating time of at least about 5 minutes.

7. The process of claim 5, wherein surface treating includes a surface treating time of greater than about 5 minutes to about 10 minutes.

8. The process of claim 5, wherein surface treating includes a surface treating time of greater than about 10 minutes to about 20 minutes.

9. The process of claim 5, wherein surface treating includes a surface treating time of greater than about 20 minutes to about 30 minutes.

10. A process comprising:
patterning an amorphous carbon hard mask with a resist stack over a substrate, the resist stack including:
at least one antireflective coating disposed over the hard mask, selected from a dielectric antireflective coating and a bottom antireflective coating; and
a photo resist layer disposed over the at least one antireflective coating; and
surface treating the substrate to remove residual photo resist under conditions that are selective to leaving the hard mask, the at least one antireflective coating, and the substrate, wherein surface treating includes using an aqueous sulfuric acid and citric acid solution for a time of about 10 minutes, and a temperature of about 55° C.

11. The process of claim 10, wherein surface treating includes using a water, sulfuric acid and citric acid solution in an H₂O:H₂SO₄:C₆H₄O₇ concentration ratio of about 100:3:2.

12. The process of claim 10, wherein surface treating includes using a water, sulfuric acid and citric acid solution in an H₂O:H₂SO₄:C₆H₄O₇ concentration ratio of about 100:2:2.

13. A process comprising:
patterning a hard mask with a patterned photo resist layer; and
surface treating the substrate to remove residual photo resist at a first etch rate under conditions that are selective to etch the hard mask at a second etch rate that is lower than the photo resist first etch rate.

14. The process of claim 13, wherein surface treating includes rinsing the photo resist with a solution selected from a mixture of at least one of aqueous ammonium hydroxide and hydrogen peroxide solution, aqueous sulfuric acid and citric acid solution, aqueous sulfuric acid and hydrogen peroxide solution, Aleg 820 solution, ozone with dilute ammonium hydroxide, ozone with dilute hydrogen fluoride, fluorozone and piranha solution.

15. The process of claim 14, wherein surface treating includes using a water, ammonium hydroxide and hydrogen peroxide solution in an H₂O:NH₄OH:H₂O₂ concentration ratio from about 5:1:1 to about 100:3:2, a time range from about 2 minutes to about 45 minutes, and a temperature range from about room temperature to about 70° C.

16. The process of claim 14, wherein surface treating includes using a water, ammonium hydroxide and hydrogen peroxide solution in an H₂O:NH₄OH:H₂O₂ concentration ratio of about 100:3:2, a time range from about 10 minutes to about 20 minutes, and a temperature range from about 30° C. to about 60° C.

17. The process of claim 13, wherein the first etch rate is at least about a hundred times faster than the second etch rate.

18. The process of claim 13, wherein the photo resist includes at least one antireflective coating selected from a dielectric antireflective coating and a bottom antireflective coating.

19. The process of claim 13, wherein the hard mask comprises carbon.

20. The process of claim 19, wherein the hard mask formed of carbon comprises amorphous carbon.

21. The process of claim 18, wherein the dielectric antireflective coating is formed above the hard mask, the bottom antireflective coating is formed above the antireflective coating, and the photo resist layer is formed above the bottom antireflective coating.

22. The process of claim 13, wherein the patterned photo resist layer is developed by a dry development process.

23. The process of claim 13, wherein the patterned photo resist layer is used as one of a plasma etch, a wet chemical etch and a dry develop mask for patterning the hard mask.

24. A process comprising:
patterning an amorphous carbon hard mask with a resist stack over a substrate, the resist stack including:
at least one antireflective coating disposed over the hard mask, selected from a dielectric antireflective coating and a bottom antireflective coating; and
a photoresist layer disposed over the at least one antireflective coating; and
surface treating the substrate to remove residual resist under conditions that are selective to leaving the hard mask, the at least one antireflective coating, and the substrate, wherein surface treating includes using an ozone-containing solution.

25. The process of claim 24, wherein surface treating includes using the ozone-containing solution and at least one of aqueous sulfuric acid and citric acid solution, aqueous sulfuric and hydrogen peroxide solution, Aleg 820 solution, ozone with dilute ammonium hydroxide, and ozone with dilute hydrogen fluoride.

26. A process comprising:
patterning an amorphous carbon hard mask with a resist stack over a substrate, the resist stack including:
at least one antireflective coating disposed over the hard mask, selected from a dielectric antireflective coating and a bottom antireflective coating; and
a photoresist layer disposed over the at least one antireflective coating; and
surface treating the substrate to remove residual resist under conditions that are selective to leaving the hard mask, the at least one antireflective coating, and the substrate, wherein surface treating includes using a sulfuric acid-containing solution.

27. The process of claim 26, wherein surface treating includes using the sulfuric acid-containing solution and at least one of aqueous citric acid, aqueous oxaloacetic acid, aqueous acetic acid, and an acetic functional group aqueous acid.

28. A process comprising:
patterning a hard mask over a substrate with a photo resist; and
surface treating the substrate to remove residual resist at a first etch rate under conditions that are selective to etching the hard mask at a second etch rate and the substrate at a third etch rate, wherein surface treating includes using an ozone-containing solution.

29. The process of claim 28, wherein surface treating includes using the ozone-containing solution and at least one of aqueous sulfuric acid and citric acid solution, aqueous sulfuric and hydrogen peroxide solution, Aleg 820 solution, ozone with dilute ammonium hydroxide, fluorozone, a sulfuric acid-containing solution, piranha solution and ozone with dilute hydrogen fluoride.

30. The process of claim 28, wherein the hard mask is formed of a carbon material deposited under conditions to have a low etch rate by the surface treatment.

31. The process of claim 30, wherein the carbon comprises an amorphous carbon material.

32. The process of claim 28, wherein the photo resist layer includes at least one antireflective coating disposed over the hard mask, selected from a dielectric antireflective coating and a bottom antireflective coating, and the photo resist layer is disposed over the at least one antireflective coating.

33. The process of claim 28, wherein the first etch rate is at least about five times greater than the second and third etch rate.

34. The process of claim 32, wherein the first etch rate is greater than an etch rate of the at least one antireflective coating.
